(19) United States
(12) Patent Application Publication
(10) Pub. No.: US 2008/0029786 A1
(43) Pub. Date: Feb. 7, 2008

(54) INTEGRATED CIRCUIT WITH SPARE CELLS

(75) Inventor: De-An Fan, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: VIA TECHNOLOGIES, INC., Taipei (TW)

(21) Appl. No.: 11/611,286

(22) Filed: Dec. 15, 2006

(30) Foreign Application Priority Data
Jul. 21, 2006 (TW) 95126693

(51) Int. Cl. H01L 27/10

(52) U.S. Cl. 257/209

(57) ABSTRACT

An integrated circuit with spare cells. The integrated circuit comprises a substrate, spare cells formed on the substrate, and a plurality of metal layers and metal vias stacked over an input or output. A metal layer outermost from the substrate, among the plurality of metal layers, electrically connects to a power or ground voltage.

### BACKGROUND OF THE INVENTION

1. Field of the Invention

The invention relates to an integrated circuit, and, more particularly, to an integrated circuit with spare cells.

2. Description of the Related Art

Development of integrated circuits normally comprises continuous tests, debugging and revision (including addition/removal of devices and cutting/connecting conductive wires) for samples designed thereby.

There may be a bug or a fault existing in the integrated circuits because of the mistake in designing. However, there are many restrictions to correct such a mistake. For example, the devices cannot be added into integrated circuits after the complete manufacturing processes. Thus, spare cells or gates are pre-provided in the integrated circuit layout during the circuits designing to correct the logic mistake in designing. The spare cells have preset electrical or logic function, which is similar to the standard cells or standard logic gates expect that the input terminal and the output terminal of the spare cell contact a power or ground voltage. The spare cells are normally disabled and would not affect logic functions of other standard cells.

FIG. 1 is a flowchart of a process of debugging an integrated circuit. The process comprises engineering change order (ECO) and fiber ion beam (FIB) revisions. After generating an integrated circuit layout (step 110), the integrated circuit is tested and debugged (step 120). The integrated circuit can be revised directly by fiber ion beam (step 130) or engineering change order (step 140). Following this revision, the integrated circuit can be revised by engineering change order and function tested (step 150 or 160), completing design of the t integrated circuit (step 170).

The engineering change order (ECO) and fiber ion beam (FIB) revisions can be performed by reconnecting the metal layer of the integrated circuit or employing a spare cell.

In conventional fiber ion beam (FIB) revisions, a metal layer is removed by etching and reconnected by metal deposition. However, there are many restrictions to perform the fiber ion beam (FIB) revision. For example, there are no other metal traces existing above the being-removed trace to perform the removing processes. Besides, the space between the removed trace and the others in the same metal layer should be broad enough for the following metal deposition. The spare cell can be employed in the fiber ion beam (FIB) revisions by reconnecting the input terminal and the output terminal of the spare cell to other cells.

Engineering change orders (ECOs) are common in design in progress owing to numerous factors including, but not limited to improving performance (timing based), enhancing functionality and/or repairing existing errors. In engineering change order (ECO) revision, photo masks are revised and functionality of most cells retained.

To protect standard cell routing from interference by spare cells, the input terminal and the output terminal of the spare cell contact a power voltage or a ground voltage through base metal layers (such as first metal layer (metal 1) or second metal layer (metal 2)), thereby complicating the engineering change orders (ECO) and fiber ion beam (FIB) revisions employing spare cells.

In fiber ion beam (FIB) revisions, when the input terminal and the output terminal of the spare cell contact a power voltage or a ground voltage through base metal layers (such as first metal layer (metal 1) or second metal layer (metal 2)), higher metal layers (such as third metal layer (metal 3) or fourth metal layer (metal 4)) formed over the base metal layers narrow cutoff regions of the base metal layers enough to prevent removal by fiber ion beams.

When engineering change orders are performed to replace the spare cell with the standard cell, a plurality of masks must be conventionally revised, with design cost increased accordingly

### BRIEF SUMMARY OF THE INVENTION

An integrated circuit with spare cells is provided in accordance with the present invention. An exemplary embodiment of an integrated circuit comprises a substrate, a plurality of spare cells formed thereon, and a plurality of metal patterns and metal via. The input terminal or the output terminal of the spare cell connects to a power voltage or a ground voltage through the plurality of metal patterns and metal vias stacked over the input and output terminal. Specifically, the outermost metal layer, outermost on the substrate among the plurality of metal layers, electrically connects to a power voltage or a ground voltage.

According to another embodiment of the present invention, the integrated circuit comprises a substrate, a spare NMOS transistor and a stacked structure formed over the spare NMOS transistor. The stacked structure comprises a plurality of metal patterns formed in the metal layers respectively and a plurality of vias connects the metal patterns. The gate electrode of the spare NMOS transistor couples to a ground voltage through the stacked structure.

According to another embodiment of the present invention, the integrated circuit comprises a substrate, a spare PMOS transistor and a stacked structure formed over the spare PMOS transistor. The stacked structure comprises a plurality of metal patterns formed in the metal layers respectively and a plurality of vias connects the metal patterns. The gate electrode of the spare PMOS transistor couples to a power voltage through the stacked structure.

The stacked structures are provided to conserve routing resources of a spare cell. In the integrated circuit, two adjacent metal layers of the plurality of metal layers constitute a square stacked structure, a rectangular stacked structure, or a crisscross stacked structure.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a flowchart of a process for debugging an integrated circuit.

FIG. 2 is a cross-section of an integrated circuit adapted for ECO and FIB debugging in accordance with an embodiment of the invention.

FIG. 3 shows an exemplary FIB debugging for an integrated circuit in accordance with the invention.

FIG. 4 is a top view of a square stacked structure of the invention.

FIG. 5 is a top view of a rectangular stacked structure of the invention.

FIG. 6a is a top view of a crisscross stacked structure of the invention.

FIG. 6b is a sectional diagram along line A-A′ of FIG. 6a.

FIG. 7 is a top view of an integrated circuit designed by APR (ARP Poison Routing) according to embodiments of the invention.

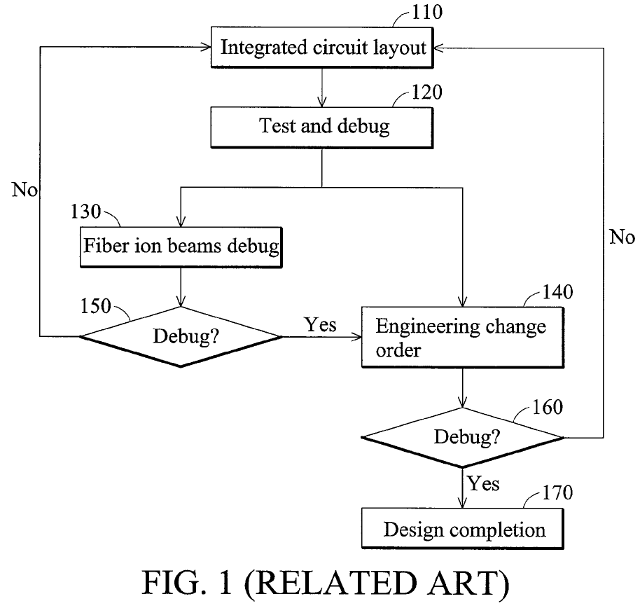

### DETAILED DESCRIPTION OF THE INVENTION

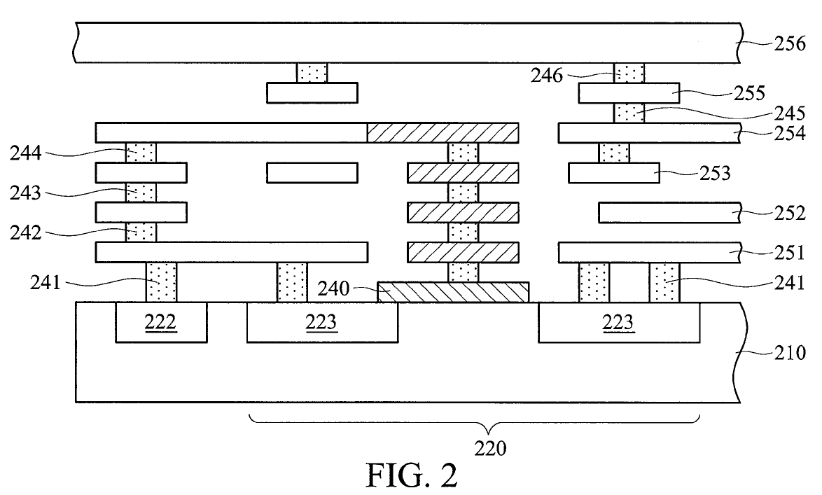

FIG. 2 shows an embodiment of an integrated circuit 200 with spare cells, comprising a p-type silicide structure and six stacked metal layers (1P6M integrated circuit). A standard cell, a spare cell 220, and a ploysilicon layer are formed on the substrate 210.

The spare cell 220 comprises a negative-channel metal oxide semiconductor (NMOS) transistor. The substrate 210 can be a p-type silicide structure and comprise a p+ doping region 222 and two n+ doping regions 223, wherein the two ends of the polysilicon layer 240 are located in the two n+ doping regions 223 respectively.

The polysilicon layer 240 serves as the gate electrode of the negative-channel metal oxide semiconductor (NMOS) transistor. One of the n+ doping regions 223 service as the source electrode of the NMOS transistor and the other n+ doping region 223 is the drain electrode of the NMOS transistor. In addition, the p+ doping region 222 is the bulk electrode of the NMOS transistor. After routing and connecting to the spare cell, the polysilicon layer 240 also serves as the input or output terminal of the spare cell 220. Further, the spare cell 220 can comprise a positive-channel metal oxide semiconductor (PMOS) transistor, a complementary metal oxide semiconductor (CMOS) transistor, or other semiconductor devices. The spare cell has a preset logic function, adapted for engineering change order (ECO) and fiber ion beam (FIB) debug.

According to the embodiment of the invention, the spare cell 220 connects to a stacked structure. The stacked structure comprises a plurality of metal patterns and a plurality of vias. The metal patterns are formed on the first metal layer 251, second metal layer 252, third metal layer 253, and fourth metal layer 254 respectively and stacked on one of the others. The vias electrically connects the metal patterns and the polysilicon layer 240 of the spare cell 220. Thus, the gate electrode of the spare cell 220 couples to a ground voltage through the stacked structure to keep the spare cell 220 disabling.

It should be noted that the input terminal and the output terminal of the spare cell are coupled to the outermost metal layer by the vias. Herein, the outermost metal layer is, for example, the sixth metal layer 256. In general, power conductive wires and ground conductive wires alternative disposed on the outermost metal layer 256. As shown in FIG. 2, a power conductive wire covers the spare cell 220 and the stacked structure. The stacked structure is connects to another ground conductive wire trough another trace on the metal layer 254 (not shown in FIG. 2). Thus, the stacked structure does not interfere with power distribution on the outermost metal layer 256.

In the semiconductor chip, two adjacent metal layers of the first metal layer 251, second metal layer 252, third metal layer 253, fourth metal layer 254, fifth metal layer 255, and sixth metal layer 256 are electrically connected by vias 242, 243, 244, 245 and 246, respectively. According to the embodiment of the invention, the plurality of metal patterns and via are stacked over the input and output terminal, wherein the outermost metal layer (the sixth metal layer 256) outermost from the substrate 210 among the plurality of metal layers, electrically connects to a power or ground voltage.

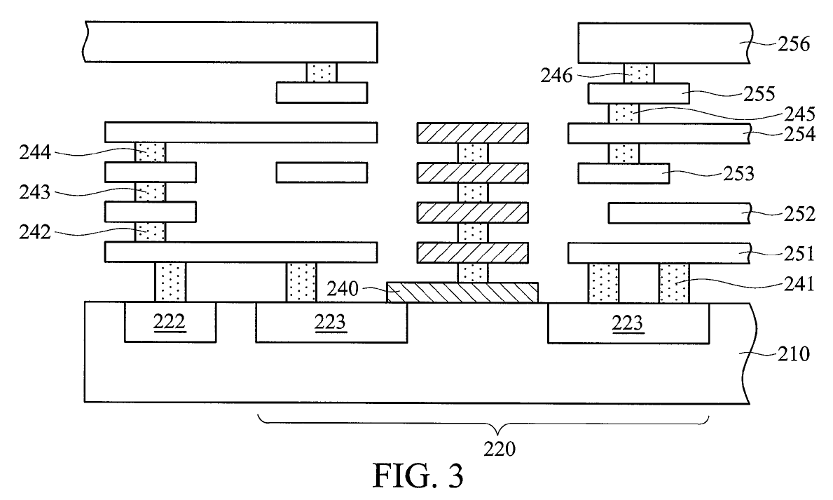

FIG. 3 shows exemplary ECO and FIB debugging for an integrated circuit in accordance with the invention, wherein, to enable the spare cell 220 by the FIB debugging, an ion beam cuts the conductive wire (the outermost metal layer 256) and cut the connective wire (fourth metal layer 254) to disconnect the ground terminal and the stacked structure. The cut-off area of the outermost metal layer 256 of the spare cell 220 is used to couple to the spare cell 220 and the other device in the further process.

Since the spare cell employs the outermost metal layer to connect to the system power voltage or ground voltage, routing resources are consumed. The invention also thus provides an integrated circuit with spare cells with metal stacked structure (such as a crisscross stacked structure) to conserve routing resources.

In another embodiment of the invention, the integrated circuit has six metal layers and a square measure of 4.4e+7 um². The quantity of standard and spare cells is 203563, wherein the ratio between the square measure occupied by the standard and spare cells and the square measure of the integrated circuit is 0.7676. Further, the ratio of spare cells to total cells (standard and spare cells) is 0.0093.

Stacked structures are provided to conserve routing resources of a spare cell. In the integrated circuit, two adjacent metal layers of the plurality of metal layers constitute a square stacked structure, a rectangular stacked structure, or a crisscross stacked structure, as disclosed below.

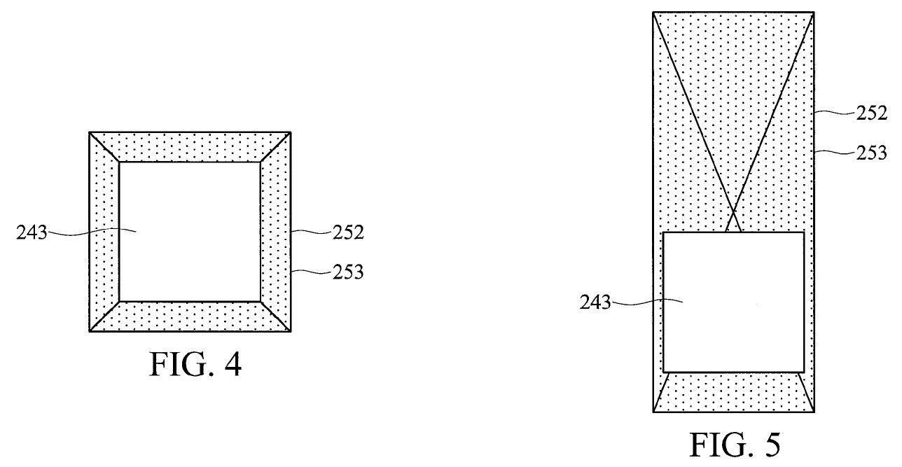

As shown in FIG. 4, a top metal layer and bottom metal layer are square and stacked, with the top and bottom metal layers being outermost from the surrounding routing.

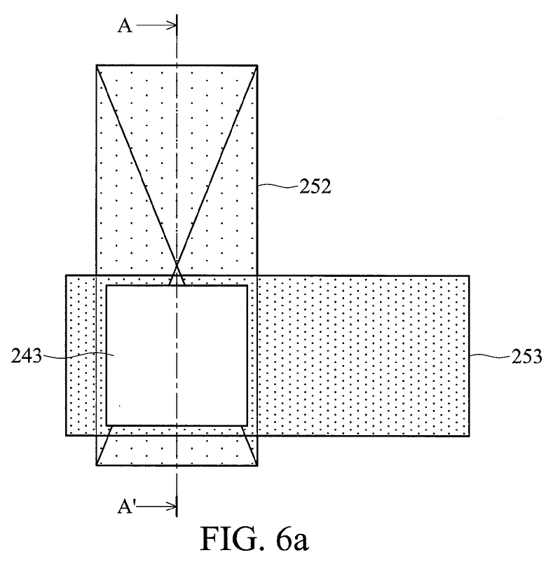

As shown in FIG. 5, a top metal layer and bottom metal layer are rectangular and stacked parallel, with the top and bottom metal layers having a shorter upward distance from the routing, and are farther from the routing downwards, and to the left and right.

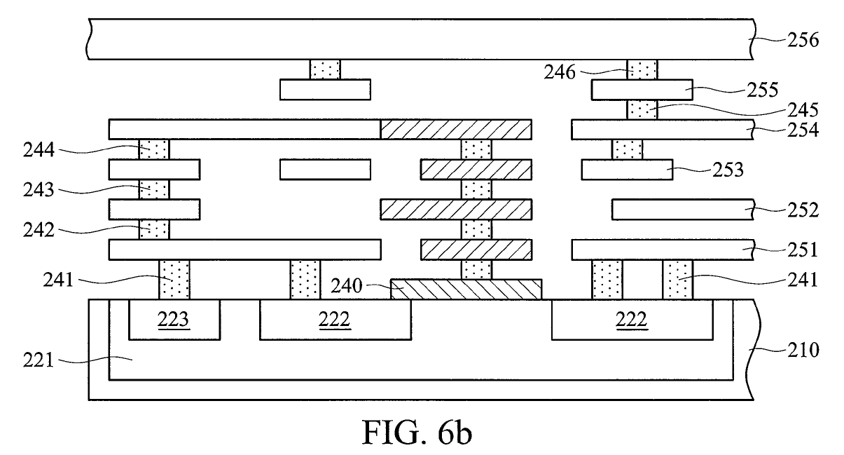

As shown in FIG. 6a, a top metal layer and bottom metal layer are rectangular and stacked vertically. For example, the first and third metal layers may be disposed along an X-axis with the second and fourth metal layers dispose along a Y-axis. FIG. 6b is a sectional diagrams along line A-A′ of FIG. 6a. The spare cell is a pMOS transistor located on the n-well 221. The pMOS transistor comprise a polysilicon layer 240, a n+ doping region 223 and two p+ doping regions 222, wherein the two ends of the polysilicon layer 240 are located in the two p+ doping regions respectively. The polysilicon layer 240 is the gate electrode of the PMOS transistor, one p+ doping region is the source electrode and the other p+ doping region is the drain electrode. Similarly, one of the p+ doping regions 222, the n+ doping region 223 and the polysilicon layer 240 of the pMOS transistor electrically connect to a power voltage to keep the pMOS transistor on disabling through the stacked structure.

The routing increase of the stacked structures is shown in Table 1.

TABLE 1

| | | Rectangular | Crisscross |
|---|---|---|---|
| | Square stacked | stacked | stacked |
| | structure | structure | structure |
| Length of routing | 24407661.43 um | 24389638.0 | 24384841.3 |
| routing increase ratio | 0.13% | 0.06% | 0.04% |

Accordingly, the crisscross stacked structure has less additional routing length, and the square stacked structure has longer additional routing length.

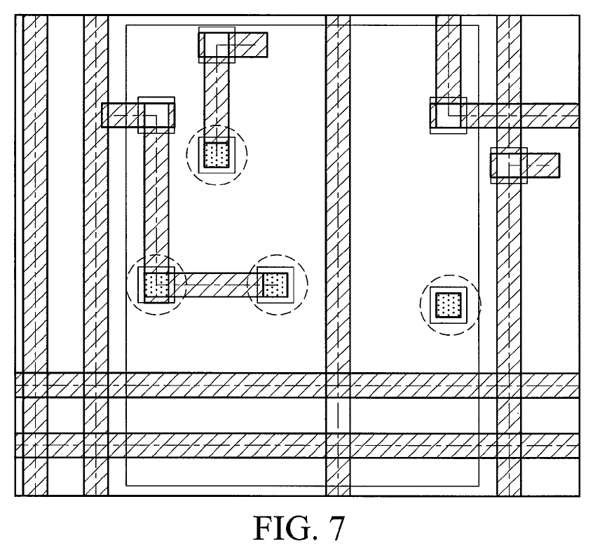

Referring to FIG. 7, according to an embodiment of the invention, the integrated circuit is designed by APR (ARP Poison Routing). The input terminal and the output terminal of the spare cell are coupled to the outermost metal layer (the fourth metal layer) through the via. Moreover, to prevent the outermost metal layer from routing by APR, the plurality of metal layers, excluding the outermost metal layer, is surrounded by a metal blockage layer.

According to the invention, when ECO is to be performed, only one metal photo mask layer need be revised to enable the spare cell. Further, since the input terminal and the output terminal of the spare cell are coupled to the outermost metal layer, no metal layer above the cutoff region of the outermost metal layer interferes with debugging by FIB, reducing costs. Moreover, routing resources are conserved.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit with spare cells, comprising:
a substrate;
a spare cell formed on the substrate, wherein the spare cell comprises an input terminal and an output terminal; and
a plurality of metal layers and metal vias stacked over the input and output terminal, wherein a metal layer outermost from the substrate, among the plurality of metal layers, electrically connects to a power or ground voltage.

2. The integrated circuit as claimed in 1, wherein two adjacent metal layers of the plurality of metal layers constitute a square stacked structure.

3. The integrated circuit as claimed in 1, wherein two adjacent metal layers of the plurality of metal layers constitute a rectangular stacked structure.

4. The integrated circuit as claimed in 1, wherein two adjacent metal layers of the plurality of metal layers constitute a crisscross stacked structure.

5. The integrated circuit as claimed in 1, wherein the substrate comprises a p-type silicon substrate.

6. The integrated circuit as claimed in 1, wherein the stacked height of the plurality of metal layers substrate does not interfere with power mapping.

7. The integrated circuit as claimed in 1, wherein the spare cell has a preset logic function, adapted for engineering change order (ECO) and fiber ion beam (FIB) debugging.

8. The integrated circuit as claimed in 1, wherein the integrated circuit is designed by APR (ARP Poison Routing).

9. The integrated circuit as claimed in 1, wherein the plurality of metal layers, excluding the outermost metal layer, is surrounded by a metal blockage layer.

10. The integrated circuit as claimed in 1, wherein the spare cell comprises a complementary metal oxide semiconductor (CMOS) device.

11. The integrated circuit as claimed in 1, wherein the spare cell comprises a negative-channel metal oxide semiconductor (NMOS) device.

12. The integrated circuit as claimed in 1, wherein the spare cell comprises a positive-channel metal oxide semiconductor (PMOS) device.

13. An integrated circuit comprising:
a substrate;
a spare negative-channel metal oxide semiconductor (NMOS) transistor formed on the substrate, wherein the spare transistor comprises a gate electrode, a source electrode and a drain electrode;
a stacked structure formed over the spare NMOS transistor, the stacked structure having a plurality of metal patterns and at least one via connecting the metal patterns,
wherein the gate electrode of the spare NMOS transistor electrically connects to a ground voltage through the stacked structure.

14. The integrated circuit as claimed in 13, wherein the metal patterns of the stacked structure are in a square shape.

15. The integrated circuit as claimed in 13, wherein the metal patterns of the stacked structure are in a rectangular shape

16. The integrated circuit as claimed in 15, wherein one of the metal patterns of the stacked structure is cross with another adjacent metal pattern.

17. An integrated circuit comprising:
a substrate;
a spare positive-channel metal oxide semiconductor(PMOS) transistor formed on the substrate, wherein the spare transistor comprises a gate electrode, a source electrode and a drain electrode;
a stacked structure formed over the spare PMOS transistor, the stacked structure having a plurality of metal patterns and at least one via connecting the metal patterns,
wherein the gate electrode of the spare PMOS transistor electrically connects to a power voltage through the stacked structure.

18. The integrated circuit as claimed in 17, wherein the metal patterns of the stacked structure are in a square shape.

19. The integrated circuit as claimed in 17, wherein the metal patterns of the stacked structure are in a rectangular shape

20. The integrated circuit as claimed in 19, wherein one of the metal patterns of the stacked structure cross with another adjacent metal pattern.
